(19) United States
(12) Patent Application Publication
(10) Pub. No.: US 2024/0413820 A1
(43) Pub. Date: Dec. 12, 2024

(54) HIGH-SIDE DRIVER CIRCUIT

(71) Applicant: ams-OSRAM AG, Premstaetten (AT)

(72) Inventor: Dominik RUCK, Lannach (AT)

(21) Appl. No.: 18/699,312

(22) PCT Filed: Oct. 11, 2022
(86) PCT No.: PCT/EP2022/078172

§ 371 Date: Apr. 8, 2024

(30) Foreign Application Priority Data
Oct. 14, 2021 (GB) 2114713.7

(51) Int. Cl. H03K 17/687; H01S 5/026; H01S 5/42

(52) U.S. Cl. CPC H03K 17/687; H01S 5/0261; H01S 5/423; H03K 2217/0063

(57) ABSTRACT

A high-side driver circuit includes a regulator circuit configured to regulate a gate voltage of a first transistor and at least one second transistor configured to drive a high-side of a load. The circuit also includes a first buffer configured to copy a voltage at a gate of the first transistor to a gate of the at least one second transistor, and a second buffer configured to copy a voltage at the high side of the load to a source of first transistor. Also disclosed is a device including the high-side driver circuit, and a system including the device and at least one array of laser diodes.

### RELATED APPLICATION(S)

This application is a US National Stage Application of International Application PCT/EP2022/078172, filed on 11 Oct. 2022, and claims priority under 35 U.S.C. § 119(a) and 35 U.S.C. § 365(b) from United Kingdom Patent Application GB 2114713.7, filed on 14 Oct. 2021, the contents of which are incorporated herein by reference in their entirety.

### TECHNICAL FIELD

The present disclosure relates to high-side driver circuits and, in particular, high-side driver circuits for driving arrays of Vertical Cavity Surface Emitting Lasers (VCSELs).

### BACKGROUND

Laser diodes, and in particular VCSELs, are implemented in various optical devices, such as proximity sensors, time-of-flight sensors and infrared illuminators. Such optical devices may be commonly implemented in portable devices such as cellular telephones, tablets, laptops and smartphones, and other industrial and automotive applications, such as in Light Detection and Ranging (LIDAR) systems, in-cabin sensing systems, surveillance systems and warehouse/transport automation systems.

Some applications may implement arrays of laser diodes comprising hundreds of even thousands of individual laser diodes. Such array may have substantial power requirements.

However, existing drivers for driving such arrays may be large, complex and expensive and may be inefficient. Furthermore, existing drivers for driving such arrays may have limited scalability, and may not be suited to providing a highly accurate control and/or addressing of laser diodes within an array.

For example, known drivers for driving such arrays may comprise a current limiting component such as a current source, and a switch configured to route a current from the source to different outputs. However, for larger arrays that may require a relatively high drive current, such drivers may become relatively large in size, e.g. have a large footprint, and may exhibit a reduced efficiency.

Furthermore, many applications of laser diodes require precise control over the operation of the laser diodes, which may be achieved by a correct and accurate control of a drive current and/or voltage level applied to the laser diodes, with an appropriate timing. Control of laser diodes may be critical in some use cases. For example, in eye-safety applications it may be essential that a provided drive current is sufficient to adequately stimulate laser diodes, yet not exceed a defined threshold that may cause the diodes to exceed a radiation threshold, potentially causing eye-damage.

However, known drivers may be particularly prone to variation in process, temperature and/or supply voltages. Such variations may directly affect an optical output of laser diodes, limiting a suitability of such drivers for driving laser diodes at or close to an eye-safety maximum emission level.

Although some laser diode driver circuits may implement some degree of monitoring of output currents and voltages, such monitoring and any adjustments to the driving of the diodes made as a result of said monitoring, may be relatively slow to implement and ineffectual. Furthermore, existing systems may be unstable under certain circumstances, or may require long settling times when driving loads.

It is therefore desirable to provide an accurate, low-complexity, and scalable driver circuit, particularly suitable for driving arrays of VCSELs. It is desirable that such a driver circuit is inexpensive, highly efficient, yet has a relatively small footprint.

At least one embodiment of at least one aspect of the present disclosure relates to obviating or at least mitigating at least one of the above identified shortcomings of the prior art.

### SUMMARY

According to a first aspect of the disclosure, there is provided a high-side driver circuit comprising: a regulator circuit configured to regulate a gate voltage of a first transistor; at least one second transistor configured to drive a high-side of a load; a first buffer configured to copy a voltage at a gate of the first transistor to a gate of the at least one second transistor; and a second buffer configured to copy a voltage at the high side of the load to a source of first transistor.

The disclosed high-side driver circuit provides an accurate, low-complexity, and scalable driver circuit, particularly suitable for driving arrays of laser diodes such as VCSELs. Furthermore, the disclosed high-side driver circuit may be implemented with a relatively small footprint.

Because the first and second buffers effectively hold the first transistor and the second transistor at the same operating point, a bias current through the first transistor is effectively the same as that through each of the at least one second transistors, scaled by a number of instantiations of second transistors and/or any variation in gate dimensions between the first and second transistors.

That is, the second transistor, which is configured a drive transistor, mirrors operation of the first transistor. Since the first transistor is regulated by the regulator circuit, the biasing current of the first transistor is known, and therefore a current provided by the second transistor can be accurately determined.

Because the first and second buffers effectively hold the first transistor and the second transistor at the same operating point, the disclosed high-side driver circuit is capable of self-compensating for variations in temperature. This is because variations in temperature may affect both the first transistor and the second transistor equally when they are provided in the same technology, for example when the circuit is implemented as a monolithic integrated circuit device.

The at least one second transistor may be an NMOS transistor.

The first transistor may be an NMOS transistor.

Use of NMOS rather than a PMOS transistor is inherently more efficient. For example, in use as a driver a PMOS driver transistor would typically require a gate voltage to be brought down to a suitable level, e.g. 5 volts or so, to enable current flow through the PMOS transistor. This would require dissipation of energy that would not is otherwise be provided to drive the load, thereby impacting an efficiency of a PMOS driver based solution.

Furthermore, NMOS transistor may be substantially quicker to switch when compared to a PMOS transistor of equivalent size.

The first buffer may be configured to maintain a gate-source voltage level of the first transistor at substantially a same voltage level as the gate-source voltage level of the at least one drive transistor.

The second buffer may be configured to maintain a source-drain voltage level of the first transistor at substantially a same voltage level as the source-drain voltage level of the at least one drive transistor.

A configuration of the first and second buffers ensures that the first transistor and the second transistor are maintained at substantially a same operating point. As such, by controlling the first transistor, e.g. regulating a bias current, accurate driving of a load by the second transistors may be achieved.

An area of the gate of the at least one second transistor may be greater than an area of the gate of the first transistor.

For example, to scale an amount of bias current in the first transistor relative to a drive current provided by the at least one second transistor, a gate of the second transistor may be substantially wider and/or be implemented with more fingers than a gate of the first transistor, thereby enabling the second transistor to have a substantially higher current capability.

The second buffer may comprise a third transistor having a gate coupled to a gate of a fourth transistor. The third transistor may be a PMOS transistor having a source coupled to the source of the first transistor. The fourth transistor may be a PMOS transistor having a source coupled to the source of the at least one second transistor.

The high-side driver circuit may comprise a current source configured to provide a biasing current to the first transistor.

The high-side driver circuit may comprise an input for providing a reference current to the current source.

Such a reference current may be provided by, or derived from, any known reference such as an on-chip bandgap reference or the like. In some embodiments, the reference current may be provided from a further regulator and/or from an off-chip source.

The high-side driver circuit may comprise at least one switch configurable to deactivate the at least one second transistor from driving the high-side of the load.

The at least one switch may be configurable to deactivate the biasing current to the first transistor.

The at least one second transistor may comprise a plurality of transistors configured to drive a high-side of the load.

That is, in some embodiments multiple instance of a NMOS drive transistor may be implemented to provide a sufficient current to drive an array of laser diodes.

According to a second aspect of the disclosure, there is provided a device comprising: the high-side driver circuit according to the first aspect; and processing circuitry configured to control at least one of: a duty cycle; a switching frequency; and/or a drive current of the high-side driver circuit.

The processing circuitry may comprise, for example, any of a logic circuit; an Arithmetic Logic Unit (ALU); a central processing unit (CPU); a combinatorial digital circuit; and/or a state machine. In yet further embodiments, at least a portion of such processing may be offloaded to an external device, e.g. an external processor or further processing circuitry.

In some examples, the device may be packaged as a Multi-Chip Module (MCM). For example, the high-side driver circuit may be implemented on a first chip, and one of more further devices such as a processors may be coupled to the first chip, wherein the chips are packaged in a single MCM package.

The device may be a monolithic device.

That is, the device may be implemented as a single integrated circuit die. In some embodiments, the device may be provided as a packaged microchip, e.g. a packaged monolithic integrated circuit.

According to a third aspect of the disclosure, there is provided a system comprising: the device according to the second aspect; and at least one array of laser diodes, wherein the device is configured to drive the at least one array of laser diodes.

The laser diodes may be VCSELs.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE DRAWINGS

In the drawings, like reference characters generally refer to the same parts throughout the different views. The drawings are not necessarily to scale, emphasis instead generally being placed upon illustrating the principles disclosed herein. These and other aspects of the present disclosure will now be described, by way of example only, with reference to the accompanying drawings, wherein:

FIG. 1 depicts an overview of a high-side driver circuit, according to an embodiment of the disclosure;

FIG. 2 depicts a more detailed view of the high-side driver circuit of FIG. 1, according to an embodiment of the disclosure:

FIG. 3 depicts a circuit diagram of high-side driver circuit, according to a further embodiment of the disclosure; and

FIG. 4 depicts a system comprising a high-side driver circuit, according to an embodiment of the disclosure.

### DETAILED DESCRIPTION OF THE DRAWINGS

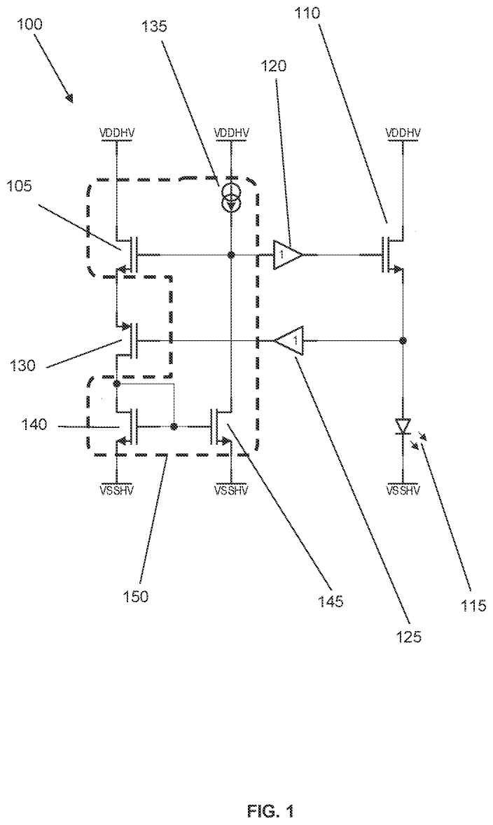

FIG. 1 depicts an overview of a high-side driver circuit 100, according to an embodiment of the disclosure.

The high-side driver circuit 100 comprises a first transistor 105. The first transistor 105 is an NMOS transistor. A drain of the first transistor 105 is coupled to a high voltage reference, denoted VDDHV. A gate voltage of the first transistor 105 is regulated, as will be described in more detail below.

The high-side driver circuit 100 comprises a second transistor 110. The second transistor 110 is an NMOS transistor. The second transistor 110 is configured to drive a high-side of a load. In the example of FIG. 1, the load is depicted as a laser diode 115. That is, a source of the second transistor 110 is coupled to an anode of the laser diode 115, and a cathode of the laser diode is coupled to a low voltage reference denoted VSSHV, e.g. a ground reference.

Although only a single laser diode 115 is depicted, it will be understood that this is merely for simplicity of illustration, and the disclosed high-side driver circuit 100 is suitable for driving a substantially greater load than a single laser diode 115, e.g. one or more arrays of laser diodes.

A first buffer 120 is configured to copy a voltage at a gate of the first transistor 105 to a gate of the second transistor 110.

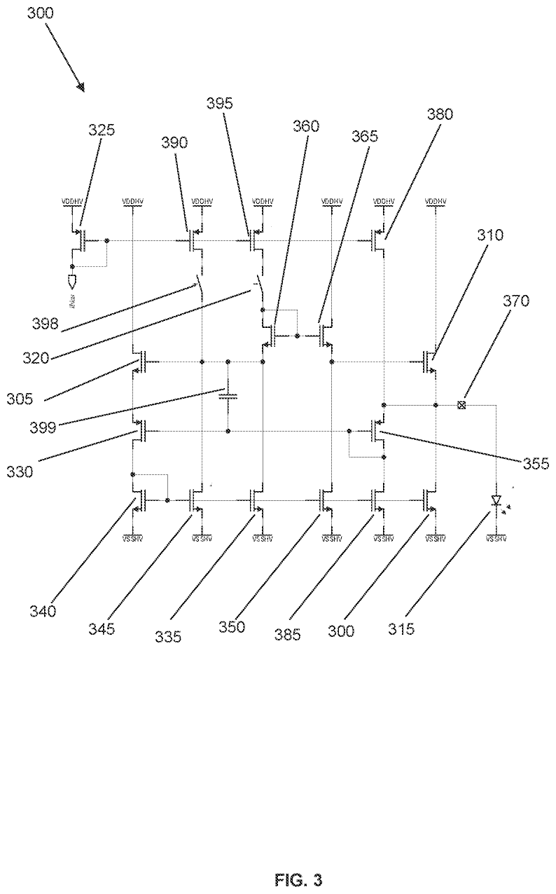

A second buffer 125 together with a third transistor 130 (which may in some embodiments be considered to be a component of the second buffer 125), is configured to copy a voltage at the high side of the load, e.g. the anode of the laser diode 115, to a source of first transistor 105. The third transistor 130 is a PMOS transistor having a source coupled to the source of the first transistor 105. Implementations of the second buffer 125 together with the third transistor 130 will be described in more detail below with respect to the detailed circuit diagram of FIG. 3.

A first current source 135 is also depicted coupled between the high voltage reference VDDHV and the gate of the first transistor 105. It should be noted that a first current source is depicted for purposes of simplicity, and generation of a specified current is described in more detail below with reference to the example embodiment high-side driver circuit 300 of FIG. 3.

The first current source 135, together with a fifth transistor 140 and sixth transistor 145 is used to regulate a gate voltage of the first transistor 105. For purposes of example, the fifth transistor 140 and the sixth transistor 145 are NMOS transistors. A drain of the fifth transistor 140 is coupled to a drain of the third transistor 130. A drain of the sixth transistor 145 is coupled to the first current source 135 and the gate of the first transistor 105. A source of the fifth transistor 140 and a source of the sixth transistor are coupled to the low voltage reference VSSHV. The gates of the fifth transistor 140 and the sixth transistor 145 are coupled to the drain of the third transistor 130. As such, the fifth transistor 140 and the sixth transistor 145 are configured as an NMOS current mirror.

Upon enabling the first current source 135, the first current source 135 provides a current that starts to increase a gate voltage of the first transistor 105.

As the gate voltage of the first transistor 105 increases, current starts to flow through the first transistor 105 from the high voltage reference VDDHV and increases a voltage at the source of the third transistor 130. A gate of the third transistor 130 is initially at a low or ground voltage and, since the third transistor 130 is a PMOS transistor, current will start to flow through the third transistor 130 once the voltage at the source of the third transistor 130 is high enough.

An increase in current flowing through the third transistor 130 will increase a voltage at the gates of the fifth transistor 140 and the sixth transistor 145. As such, the sixth transistor 145 starts conducting, effectively counteracting a current from the first current source 135. Once the current from the first current source 135 and through the sixth transistor 145 are equal, the circuit has stabilized, thereby regulating the voltage at the gate of the first transistor 105. Under these conditions, the gate voltage of the first transistor 105 is high enough to enable current to flow through the fifth transistor 140. Thus, the first current source 135 together with the fifth transistor 140, the sixth transistor 145 and the first transistor 105 act as regulator circuit 150, to regulate a voltage at the gate of the first transistor 105.

While this regulation occurs, the first buffer 120 is configured to copy the voltage at the gate of the first transistor 105 to the gate of the second transistor 110. That is, the first buffer 120 is configured to maintain a gate-source voltage level of the first transistor 105 at substantially a same voltage level as the gate-source voltage level of the second transistor 110. This enables current flow through the second transistor 110, thereby providing current to the load, e.g. the laser diode 115. That is, the voltage at the gate of the first transistor 105 has the effect of forcing a copy of the current through the first transistor 105 into the laser diode 115. In embodiments, an area of the gate of the second transistor 110, e.g. defined by its width and/or number of fingers, is greater than an area of the gate of the first transistor 105, thereby increasing a current through the second transistor 110 relative to a current through the first transistor 105. For example, in an embodiment a current through the second transistor 110 may be in the region of 100 or 1000 times greater than a current through the first transistor 105.

As a voltage at the laser diode 115 increases, the second buffer 125 together with the third transistor 130 copy the voltage at the anode of the laser diode 115 onto the source of the first transistor 105. That is, second buffer 125 is configured to push a source-drain voltage level of the first transistor 105 towards substantially a same voltage level as the source-drain voltage level of the second transistor 110.

Finally, the source-drain voltage of the first transistor 105 and the second transistor 110 are substantially equal and the gate-source voltage of the first transistor 105 and the second transistor 110 are substantially equal.

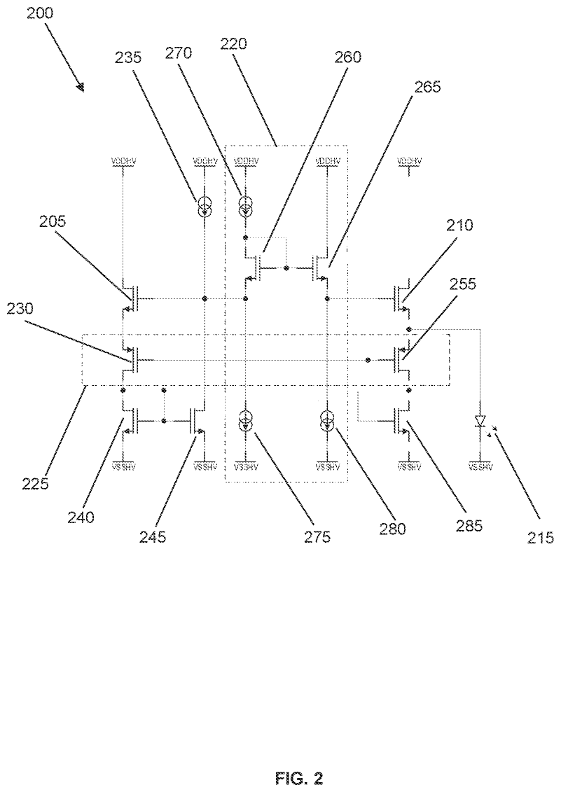

FIG. 2 depicts a high-side driver circuit 200, which corresponds to a more detailed view of the high-side driver circuit 100 of FIG. 1.

The high-side driver circuit 200 comprises a first transistor 205. The first transistor 205 is an NMOS transistor. A drain of the first transistor 205 is coupled to a high voltage reference, denoted VDDHV. A gate voltage of the first transistor 205 is regulated, as will be described in more detail below.

The high-side driver circuit 200 comprises a second transistor 210. The second transistor 210 is an NMOS transistor. The second transistor 210 is configured to drive a high-side of a load. In the example of FIG. 2, the load is depicted as a laser diode 215. That is, a source of the second transistor 210 is coupled to an anode of the laser diode 215, and a cathode of the laser diode is coupled to a low voltage reference denoted VSSHV, e.g. a ground reference.

Although only a single laser diode 215 is depicted, it will be understood that this is merely for simplicity of illustration, and the disclosed high-side driver circuit 200 is suitable for driving a substantially greater load than a single laser diode 215, e.g. one or more arrays of laser diodes.

A first buffer 220 is configured to copy a voltage at a gate of the first transistor 205 to a gate of the second transistor 210. The first buffer 120 is described in more detail below

A second buffer 225 is configured to copy a voltage at the high side of the load, e.g. the anode of the laser diode 215, to a source of first transistor 205. The second buffer 225 comprises a third transistor 230 and a fourth transistor 255.

The third transistor 230 is a PMOS transistor having a source coupled to the source of the first transistor 205. The fourth transistor 255 is also a PMOS transistor, and has a source coupled to the source of the second transistor 210. A gate of the third transistor 230 is coupled to a gate of the fourth transistor 255 and the drain of the fourth transistor.

A first current source 235 is also depicted coupled between the high voltage reference VDDHV and the gate of the first transistor 205. It should be noted that a first current source is depicted for purposes of simplicity, and generation of a specified current is described in more detail below with reference to the example embodiment high-side driver circuit 300 of FIG. 3.

The first current source 235, together with a fifth transistor 240 and sixth transistor 245 is used to regulate a gate voltage of the first transistor 205. For purposes of example, the fifth transistor 240 and the sixth transistor 245 are NMOS transistors. A drain of the fifth transistor 240 is coupled to a drain of the third transistor 230. A drain of the sixth transistor 245 is coupled to the first current source 235 and the gate of the first transistor 205. A source of the fifth transistor 240 and a source of the sixth transistor 245 are coupled to the low voltage reference VSSHV. The gates of the fifth transistor 240 and the sixth transistor 245 are coupled to the drain of the third transistor 130. As such, the fifth transistor 240 and the sixth transistor 245 are configured as an NMOS current mirror.

Upon enabling the first current source 235, the first current source 235 provides a current that starts to increase a gate voltage of the first transistor 205.

As the gate voltage of the first transistor 205 increases, current starts to flow through the first transistor 205 from the high voltage reference VDDHV and increases a voltage at the source of the third transistor 230. A gate of the third transistor 230 is initially at a low or ground voltage and, since the third transistor 230 is a PMOS transistor, current will start to flow through the third transistor 230 once the voltage at the source of the third transistor 230 is high enough.

An increase in current flowing through the third transistor 230 will increase a voltage at the gates of the fifth transistor 240 and the sixth transistor 245. As such, the sixth transistor 245 starts conducting, effectively counteracting a current from the first current source 235. Once the current from the first current source 235 and through the sixth transistor 245 are equal, the circuit has stabilized, thereby regulating the voltage at the gate of the first transistor 205. Under these conditions, the gate voltage of the first transistor 205 is high enough to enable current to flow through the fifth transistor 240. Thus, the first current source 235 together with the fifth transistor 240, the sixth transistor 245 and the first transistor 205 act as regulator circuit 250, to regulate a voltage at the gate of the first transistor 205.

While this regulation occurs, the first buffer 220 is configured to copy the voltage at the gate of the first transistor 205 to the gate of the second transistor 210.

That is, the first buffer 220 is configured to maintain a gate-source voltage level of the first transistor 205 at substantially a same voltage level as the gate-source voltage level of the second transistor 210. This enables current flow through the second transistor 210, thereby providing current to the load, e.g. the laser diode 215. That is, the voltage at the gate of the first transistor 205 has the effect of forcing a copy of the current through the first transistor 205 into the laser diode 215. In embodiments, an area of the gate of the second transistor 210, e.g. defined by its width and/or number of fingers, is greater than an area of the gate of the first transistor 205, thereby increasing a current through the second transistor 210 relative to a current through the first transistor 205. For example, in an embodiment a current through the second transistor 210 may be in the region of 100 or 1000 times greater than a current through the first transistor 205.

For purposes of example, the first buffer 220 comprises a seventh transistor 260 and an eighth transistor 265. The example first buffer 220 is formed from NMOS transistors for purposes of example only, and in other embodiments other buffers may be implemented, such as using PMOS transistors or different circuit.

A second current source 270 for providing a biasing current to the seventh transistor 260 is provided between the high voltage reference VDDHV and a drain of the seventh transistor 260. A drain of the eighth transistor 265 is coupled to the high voltage reference VDDHV. The drain and a gate of the seventh transistor 260 are coupled to a gate of the eighth transistor 265.

Also depicted is a third current source 275 for providing a biasing current coupled between the low voltage reference VSSHV and the source of the seventh transistor 260. Also depicted is a fourth current source 280 for providing a biasing current coupled between the low voltage reference VSSHV and the source of the eighth transistor 265.

A source of the seventh transistor 260 is coupled to the gate of the first transistor 205 and a source of the eighth transistor 265 is coupled to the gate of the second transistor 210.

As such, the example first buffer 220 comprises a seventh transistor 260 and an eighth transistor 265 arranged as an NMOS current mirror.

In order for the seventh transistor 260 and the eighth transistor 265 to operate effectively as a buffer, the seventh transistor 260 and the eighth transistor 265 should have the same drain-source current. The third current source 275 and fourth current source 280 ensure that the seventh transistor 260 and the eighth transistor 265 respectively have the same biasing point.

As a voltage at the laser diode 215 increases, the second buffer 225 copies the voltage at the anode of the laser diode 215 onto the source of the first transistor 205. That is, second buffer 225 is configured to push a source-drain voltage level of the first transistor 205 towards substantially a same voltage level as the source-drain voltage level of the second transistor 210.

Finally, the source-drain voltage of the first transistor 205 and the second transistor 210 are substantially equal and the gate-source voltage of the first transistor 205 and the second transistor 210 are substantially equal.

Also depicted in the example embodiment of FIG. 2 is a ninth transistor 285. In this example, the ninth transistor 285 is an NMOS transistor having a source coupled to the low voltage reference VSSHV and a drain coupled to the drain of the fourth transistor 255. A gate of the ninth transistor 285 is also coupled to the gates of the fifth transistor 240. The ninth transistor 285 together and the fifth transistor 240 ensure a same biasing point for the fourth transistor 255 and the third transistor 230 respectively.

FIG. 3 depicts a high-side driver circuit 300 corresponding to a high-side driver circuit according to a further embodiment of the disclosure.

The high-side driver circuit 300 share many of the same features as the high-side driver circuit 200 of FIG. 2 and so, for purposes of brevity, only substantial differences between the high-side driver circuit 200 of FIG. 2 and the high-side driver circuit 300 of FIG. 3 are described. That is, the high-side driver circuit 300 comprises a first transistor 305, a second transistor 310, a third transistor 330, a fourth transistor 355, a fifth transistor 340, a sixth transistor 345, a seventh transistor 360, an eighth transistor 365 and a ninth transistor 385 that correspond to the first transistor 205, second transistor 210, third transistor 230, fourth transistor 255, fifth transistor 240, sixth transistor 245, seventh transistor 260, eighth transistor 265 and ninth transistor 285 of the high-side driver circuit 200 of FIG. 2 respectively.

Instead of a first current source 235 as depicted in the high-side driver circuit 200 of FIG. 2, in the example high-side driver circuit 300 a tenth transistor 390 is depicted. The tenth transistor 390 is a PMOS transistor having a source coupled to the high voltage reference VDDHV and a drain coupled to the gate of the first transistor 305 via a first switch 398. For simplicity of illustration, the first switch 398 is simply denoted using a generic switch symbol.

Instead of a second current source 270 as depicted in the high-side driver circuit 200 of FIC 2, in the example high-side driver circuit 300 an eleventh transistor 395 is depicted. The eleventh transistor 395 is a PMOS transistor having a source coupled to the high voltage reference VDDHV and a drain coupled to a gate of the seventh transistor 360 via a second switch 320. For simplicity of illustration, the second switch 320 is simply denoted using a generic switch symbol.

A biasing current is provided to the gates of the tenth transistor 390 and the eleventh transistor 395 by a twelfth transistor 325.

The twelfth transistor 325 operates as a current source. In the example high-side driver circuit 300, the twelfth transistor 325 is a PMOS transistor having a source coupled to the high voltage reference VDDHV. A drain of the twelfth transistor 325 is coupled to a gate of the twelfth transistor 325 and to the gates of the tenth transistor 390 and the eleventh transistor 395.

A reference current, denoted “ibias”, is provided to the drain of the twelfth transistor 325. The reference current “ibias” may, for example, be generated by an on-chip reference such as a bandgap reference or the like. In some examples, the reference current “ibias” may be provided from an external source to a pin, ball or pad of a device implementing the high-side driver circuit 300.

In an example of a use case, a reference current “ibias” in the range of tens of milliamps may be provided. As described above with reference to FIGS. 1 and 2, the high-side driver circuit 300 may provide a substantial current multiplication factor. For example, a current through the second transistor 110 and delivered to a load, e.g. a VCSEL array, may be in the region of 100 or 1000 times greater than a current through the first transistor 105 due to the reference current “ibias”. Note that the load is again simply depicted as a single laser diode 315 in FIG. 3 for purposes of illustration, but the high-side driver circuit 300 may be suitable for driving large arrays of laser diodes, e.g. arrays of hundreds or even thousands of VCSELs. Furthermore, the laser diode 315 is depicted as coupled to the high-side driver circuit 300 via a pad 370, indicating that the high-side driver circuit 300 may be implemented on an integrated circuit, e.g. as a monolithic device, and coupled to a n off-chip load via a pad, pin ball or the like.

The above-described regulation of the circuit commences when the first switch 398 and the second switch 320 are closed. That is, the first switch 398 and the second switch 320 are configurable to deactivate the biasing current to the first transistor 305 and to deactivate the second transistor 310 from driving the high-side of the load, e.g. laser diode 315.

Instead of a third current source 275 as depicted in the high-side driver circuit 200 of FIG. 2, in the example high-side driver circuit 300 a thirteenth transistor 335 is depicted. The thirteenth transistor 335 is an NMOS transistor having a source coupled to the low voltage reference VSSHV and a drain coupled to the source of the seventh transistor 360.

Instead of a fourth current source 280 as depicted in the high-side driver circuit 200 of FIG. 2, in the example high-side driver circuit 300 a fourteenth transistor 350 is depicted. The fourteenth transistor 350 is an NMOS transistor having a source coupled to the low voltage reference VSSHV and a drain coupled to a source of the eighth transistor 365.

The thirteenth transistor 335 and fourteenth transistor 350 provide biasing points for the first buffer, e.g. for the seventh transistor 360 and eighth transistor 365 respectively.

In the example high-side driver circuit 300, a fifteenth transistor 375 is implemented. The fifteenth transistor 375 is an NMOS transistor having a source coupled to the low voltage reference VSSHV and a drain coupled to the source of the second transistor 310, and therefore to the anode of the laser diode 315. In the event that the laser diode 315 is deactivated by opening the first switch 398 and the second switch 320, the fifteenth transistor 375 may deplete the laser diode 215, ensuring a short switch-off time for the laser diode 315.

Also depicted is a sixteenth transistor 380 which, in a similar to the tenth transistor 390 and eleventh transistor 395, is a PMOS transistor having a source coupled to the high voltage reference VDDHV and a gate coupled to the gate of the twelfth transistor 325. As such, the sixteenth transistor 380 provides a biasing current to the fourth transistor 355.

In some embodiments, a capacitor 399 may be implemented. The capacitor 399 provides stability to the regulation. In the example high-side driver circuit 300, the capacitor 399 provide high frequency coupling between the gate of the first transistor 305 and the gates of the third transistor 330 and fourth transistor 355, e.g. the second buffer.

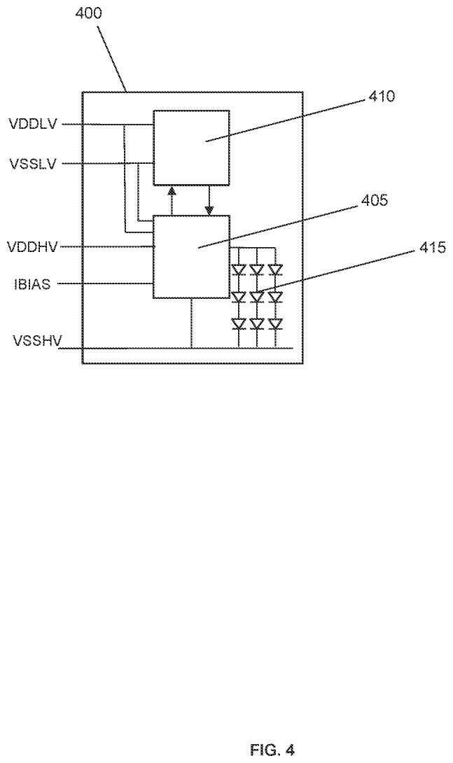

FIG. 4 depicts an example system 400 comprising a high-side driver circuit, according to an embodiment of the disclosure. The example system 400 comprises a device 405. The device 405 comprises the high-side driver circuit 100, 200, 300 as described above. In some example embodiments, the device 405 may also comprise processing circuitry configured to control at least one of: a duty cycle; a switching frequency; and/or a drive current of the high-side driver circuit 100, 200, 300.

In the depicted example system 400, the high-side driver circuit 100, 200, 300 is provided as a monolithic device and a separate processing device 410 comprising the processing circuitry is provided. The processing device 410 is communicably coupled to the device 405. In an example, the processing device 410 may control the first switch 398 and the second switch 320 of the high-side driver circuit 300. The processing circuitry may comprise, for example, any of: a logic circuit; an Arithmetic Logic Unit (ALU); a central processing unit (CPU); a combinatorial digital circuit; and/or a state machine

Also depicted is an input for providing the current “ibias” to the high-side driver circuit 300 in the device 405. In other embodiments, the reference current “ibias” may be generated in the device 405, and/or the reference current “ibias” may be controlled by the processing device 410.

Also depicted in FIG. 4 is array of laser diodes 415 driven by the high-side driver circuit 100, 200, 300 in the device 405. Although for illustrative purposes only nine laser diodes are depicted, it will be appreciated that the disclosed device 405 may be configured to drive substantially larger laser diode arrays, for example comprising hundreds or even thousands of laser diodes. The laser diodes may be VCSELs

Although the disclosure has been described in terms of embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

LIST OF REFERENCE NUMERALS

| | |
|---|---|
| 100 | high-side driver circuit |
| 105 | first transistor |
| 110 | second transistor |
| 115 | laser diode |
| 120 | first buffer |
| 125 | second buffer |
| 130 | third transistor |
| 135 | first current source |
| 140 | fifth transistor |
| 145 | sixth transistor |
| 150 | regulator circuit |
| 200 | high-side driver circuit |
| 205 | first transistor |
| 210 | second transistor |
| 215 | laser diode |
| 220 | first buffer |
| 225 | second buffer |
| 230 | third transistor |
| 235 | first current source |
| 240 | fifth transistor |
| 245 | sixth transistor |
| 250 | regulator circuit |
| 255 | fourth transistor |
| 260 | seventh transistor |
| 265 | eighth transistor |
| 270 | second current source |
| 275 | third current source |
| 280 | fourth current source |
| 285 | ninth transistor |
| 300 | high-side driver circuit |
| 305 | first transistor |
| 310 | second transistor |
| 315 | laser diode |
| 320 | second switch |
| 325 | twelfth transistor |
| 330 | third transistor |
| 335 | thirteenth transistor |
| 340 | fifth transistor |
| 345 | sixth transistor |
| 350 | fourteenth transistor |
| 355 | fourth transistor |
| 360 | seventh transistor |
| 365 | eighth transistor |
| 370 | pad |
| 375 | fifteenth transistor |
| 380 | sixteenth transistor |
| 385 | ninth transistor |
| 390 | tenth transistor |
| 395 | eleventh transistor |
| 398 | first switch |
| 399 | capacitor |
| 400 | system |
| 405 | device |
| 410 | processing device |
| 415 | array of laser diodes |
| IBIAS | Reference current |
| VDDHV | high voltage reference |
| VSSHV | low voltage reference |

What is claimed is:

1. A high-side driver circuit, comprising:
a regulator circuit configured to regulate a gate voltage of a first transistor;
at least one second transistor configured to drive a high-side of a load;
a first buffer configured to copy a voltage at a gate of the first transistor to a gate of the at least one second transistor; and
a second buffer configured to copy a voltage at the high side of the load to a source of first transistor.

2. The high-side driver circuit of claim 1, wherein the at least one second transistor is an NMOS transistor.

3. The high-side driver circuit of claim 1, wherein the first transistor is an NMOS transistor.

4. The high-side driver circuit of claim 1, wherein the first buffer is configured to maintain a gate-source voltage level of the first transistor at substantially a same voltage level as the gate-source voltage level of the at least one second transistor.

5. The high-side driver circuit of claim 1, wherein the second buffer is configured to maintain a source-drain voltage level of the first transistor at substantially a same voltage level as the source-drain voltage level of the at least one second transistor.

6. The high-side driver circuit of claim 1, wherein an area of the gate of the at least one second transistor is greater than an area of the gate of the first transistor.

7. The high-side driver circuit of claim 1, wherein the second buffer comprises a third transistor having a gate coupled to a gate of a fourth transistor, wherein:
the third transistor is a PMOS transistor having a source coupled to the source of the first transistor; and
the fourth transistor is a PMOS transistor having a source coupled to the source of the at least one second transistor.

8. The high-side driver circuit of claim 1, comprising a current source configured to provide a biasing current to the first transistor.

9. The high-side driver circuit of claim 8, comprising an input for providing a reference current (IBIAS) to the current source.

10. The high-side driver circuit of claim 1, comprising at least one switch configurable to deactivate the at least one second transistor from driving the high-side of the load.

11. The high-side driver circuit of claim 8, wherein the at least one switch is configurable to deactivate the biasing current to the first transistor.

12. The high-side driver circuit of claim 1, wherein the at least one second transistor comprises a plurality of transistors configured to drive a high-side of the load.

13. A device comprising:
a high-side driver circuit comprising:
a regulator circuit configured to regulate a gate voltage of a first transistor;
at least one second transistor configured to drive a high-side of a load;
a first buffer configured to copy a voltage at a gate of the first transistor to a gate of the at least one second transistor; and
a second buffer configured to copy a voltage at the high side of the load to a source of first transistor; and
processing circuitry configured to control at least one of: a duty cycle; a switching frequency; and/or a drive current of the high-side driver circuit.

14. The device of claim 13, wherein the device is as a monolithic device.

15. A system comprising:
a device comprising:
a high-side driver circuit comprising:
a regulator circuit configured to regulate a gate voltage of a first transistor:
at least one second transistor configured to drive a high-side of a load:
a first buffer configured to copy a voltage at a gate of the first transistor to a gate of the at least one second transistor; and
a second buffer configured to copy a voltage at the high side of the load to a source of first transistor; and
processing circuit configured to control at least one of: a duty cycle; a switching frequency; and/or a drive current of the high-side driver circuit; and
at least one array of laser diodes;
wherein the device is configured to drive the at least one array of laser diodes.
